(19) United States
(12) Patent Application Publication
(10) Pub. No.: US 2026/0186197 A1
(43) Pub. Date: Jul. 2, 2026

(54) ELECTRONIC DEVICE AND MEANS OF TRANSPORT

(71) Applicant: Continental Automotive Technologies GmbH, Hannover (DE)

(72) Inventor: Marcus Koch, Waldbronn (DE)

(73) Assignee: Continental Automotive Technologies GmbH, Hannover (DE)

(21) Appl. No.: 18/861,380

(22) PCT Filed: May 12, 2023
(86) PCT No.: PCT/DE2023/200096

§ 371 Date: Oct. 29, 2024

(30) Foreign Application Priority Data
May 20, 2022 (DE) 10 2022 205 049.5

(51) Int. Cl. F21V 8/00; H05K 7/20

(52) U.S. Cl. CPC G02B 6/0085; H05K 7/20409; H05K 7/20963

(57) ABSTRACT

An electronic device comprising a carrier element and at least one heat-producing electronic component is disclosed. The carrier element is configured as a steam chamber and is designed to distribute heat produced by the electronic component.

### CROSS REFERENCE TO RELATED APPLICATION

This US patent application claims the benefit of PCT patent application No. PCT/DE 2023/200096, filed May 12, 2023, which claims the benefit of German patent application No. 10 2022 205 049.5, filed May 20, 2022, both of which are hereby incorporated by reference.

### TECHNICAL FIELD

The present disclosure relates to an electronic device and to a means of transportation having such an electronic device.

### BACKGROUND

The number and area of display devices in means of transportation are constantly increasing. Display devices may be found on the market for example as an instrument cluster for the driver, as a central display and also as a front-seat passenger display. Non-luminous transmissive display devices require a backlight to present images. The task of the backlight here is to illuminate the display panel used as uniformly as possible over the entire active surface in order to produce a display that is as homogeneous as possible right up to the peripheral region. A display that is as bright as possible is achieved due to the fact that the alignment of a liquid crystal layer of the display panel in combination with the alignment of polarizing filters permits maximum transmission.

Especially for TFT displays (TFT: thin-film transistor), there is a problem with local heating caused by light-emitting diodes. This is the case particularly with so-called edge backlights, i.e. backlights in which the light-emitting diodes are arranged at the periphery of the display panel. With this design, the region of the polarizing filters in the vicinity of the light-emitting diodes is heated. This may lead to destruction of the polarizing filters since the heating can cause brownish discoloration of the polarizing filters.

In other electronic devices too, heat is often generated by one or more individual small components, while the rest of the device remains relatively cool. These hot components are usually bonded to a heat sink, very often to the metal housing of the device itself, using thermally conductive paste or thermally conductive pads. Heat transfer is greatly limited by the thermal capacity of this thermal connection and by the thermal resistance of the heat sink itself.

In order to overcome the limited thermal capacity, many electronic devices use heat transfer by air convection, or even deploy a fan or a blower to direct cool air to the hot components or heat sinks and discharge the heated air.

In mobile telephones, laptops and games consoles, what are often referred to as heat pipes are sometimes used to transport heat from a hot processor to a cool heat sink. The heat pipes and heat sinks are additional components within a housing here. The heat sink still requires air convection or even a fan in order to be cooled. In addition, a special thermal connection to the heat pipe is often required, such as thermally conductive paste, thermally conductive pads or an expensive soldering process for example.

In this context, US 2004/0228110 A1 describes a backlight with high heat dissipation. The backlight has a large number of light sources, which are positioned on the rear side of a display panel. The light sources are enclosed by a housing which is connected to the diffuser and is configured to reflect the light beams to the diffuser. The housing contains a heat pipe which serves as an interface for heat transfer between the backlight and the outside environment.

As an alternative to the tubular heat pipes, flat heat pipes, what are known as steam chambers or vapor chambers, are also available. These are not usually used for transporting heat, but rather for spreading heat. In the case of heat pipes and steam chambers, cooling is based on the change in the physical state or the change in the phase of a liquid inside the chamber which is associated with an energy exchange due to physical processes by evaporation or condensation. The ability to absorb or dissipate thermal energy is thus considerably better than pure heat transfer in a solid component.

In this context, US 2014/0262160 A1 describes a device for the management of heat that is generated by an electronic component of a mobile device. The device comprises a housing for receiving the electronic component and a steam chamber arranged in the housing. The steam chamber has a cavity, which is defined by a front wall and a rear wall. An outer surface of the housing comprises at least a portion of the rear wall of the steam chamber here.

### SUMMARY

It is an object of the disclosure to provide solutions for improved thermal management for an electronic device.

This object is achieved by an electronic device having the features of claim 1 and by a means of transportation as claimed in claim 10. Preferred configurations of the disclosure are the subject matter of the dependent claims.

According to a first aspect of the disclosure, an electronic device has a carrier element and at least one heat-producing electronic component, wherein the carrier element is configured as a steam chamber and is designed to distribute heat produced by the electronic component.

In many electronic devices, it is not the total amount of heat introduced that is problematic, but rather the local heat input by individual electronic components. The aim of thermal management is therefore to eliminate such hot spots. Steam chambers allow the locally introduced heat to be distributed and thus allow the temperature at the hot spots to be reduced. They absorb the heat where it is produced and pass it on to the coolest point in the steam chamber, no matter where this is. Changes over time are also automatically compensated for since evaporation and condensation always takes place where the heat input is high enough or the temperature is low enough. In the solution according to the invention, it is now provided that a carrier element of the electronic device, which carrier element absorbs the mechanical loads of the electronic device, is simultaneously configured as a steam chamber, i.e. the carrier element and the steam chamber are one part. Such a carrier element is typically manufactured by means of die-casting and has a significantly larger mass than is the case with the sheet-metal housings of previous steam chambers. Therefore, the carrier element simultaneously acts as a heat sink, and therefore no additional heat sink is required. Instead, those regions of the carrier element which would have remained cool without the configuration as a steam chamber are also used for the heat distribution in the solution according to the invention. In this way, very uniform heat distribution is achieved. In addition, the system is quiet and wear-free.

According to one aspect of the disclosure, the heat-producing electronic component is thermally connected to the carrier element. Owing to the thermal connection, very good heat dissipation from the electronic component to the evaporator of the steam chamber is achieved. This allows the locally introduced heat to be distributed quickly. The thermal connection may, in particular, involve the electronic component being arranged on the carrier element. An additional connection using thermally conductive paste or a thermally conductive pad may be provided, but is not required.

According to one aspect of the disclosure, the electronic device is a display device. A series of electronic components which produce heat locally are generally installed in the display device. Particularly in the case of display devices for the automotive sector, an additional problem is that they have to be operated in a very warm environment at least at times, this making thermal management more difficult. This problem may be easily handled by the solution according to the invention. However, the solution according to the disclosure may also be used in other devices which have a comparatively cool housing and in which individual components produce a large amount of heat. Examples include control units, computer camera systems or mobile telephones.

According to one aspect of the disclosure, the heat-producing electronic component is a light-emitting diode of a backlight. The backlights of display devices generally include a large number of light-emitting diodes that require thermal management. This presents a challenge particularly in the automotive sector since, for example, freestanding displays still have to provide a high luminance even at high ambient temperatures. New technologies, such as disappearance technology, active privacy or improved glare prevention using light control films (LCF), which require high light output, as well as increasingly larger head-up displays, also require new, quiet and wear-free cooling concepts.

According to one aspect of the disclosure, the carrier element is configured as a housing. In this way, another function is transferred to the carrier element. Not only does it absorb the mechanical loads of the electronic device but it also seals off the electronic device from the environment at the same time. Furthermore, the carrier element may also be provided with fastening elements for the installation of the electronic device in accordance with the intended application.

According to one aspect of the disclosure, an outer wall of the carrier element is configured as a heat sink. This outer wall then serves as a condenser of the steam chamber at the same time. For example, the outer wall may be thicker than would be required for stability reasons, in order to thus provide more mass for heat distribution.

According to one aspect of the disclosure, the outer wall has cooling fins. The use of cooling fins may increase the dissipation of heat to the environment if this is necessary.

According to one aspect of the disclosure, the carrier element is manufactured by internal-pressure injection molding. For internal-pressure injection molding, casting material is first injected into a casting mold. A temporary liquid or gaseous filler is then injected into the mold with the still liquid casting material in such a way that it acts as a core. The displacement of the casting material from the center firstly creates a cavity and secondly the casting material is pressed against the walls of the casting mold. Once the casting material has solidified, the filler escapes again. The required liquid can then be introduced into the resulting hollow body and the hollow body can then be closed.

According to one aspect of the disclosure, the steam chamber is lined with a porous material. The porous material uses the capillary effect and ensures that the liquid in the steam chamber is returned to the evaporator after condensation.

An electronic device according to the disclosure is preferably used in a means of transportation. The means of transportation may be, for example, a motor vehicle, but alternatively may also be an aircraft, a rail vehicle or a watercraft.

### BRIEF DESCRIPTION OF THE DRAWINGS

Further features of the present disclosure will become apparent from the following description and the appended claims in conjunction with the figures, wherein:

FIG. 1 schematically shows a first embodiment of an electronic device according to the disclosure;

FIG. 2 illustrates the manner of operation of a steam chamber of the electronic device from FIG. 1;

FIG. 3 schematically shows a second embodiment of an electronic device according to the disclosure;

FIG. 4 schematically shows a third embodiment of an electronic device according to the disclosure;

FIG. 5 schematically shows a possible design of channels of a steam chamber of the electronic device from FIG. 4; and

FIG. 6 schematically shows a means of transportation that uses an electronic device according to the disclosure.

### DETAILED DESCRIPTION

For a better understanding of the principles of the present disclosure, embodiments of the disclosure are explained in more detail below with reference to the figures. Identical reference signs are used for identical or functionally identical elements in the figures and are not necessarily described again for each figure. It goes without saying that the disclosure is not restricted to the embodiments represented and that the features described may also be combined or modified without departing from the scope of protection of the disclosure as defined in the appended claims.

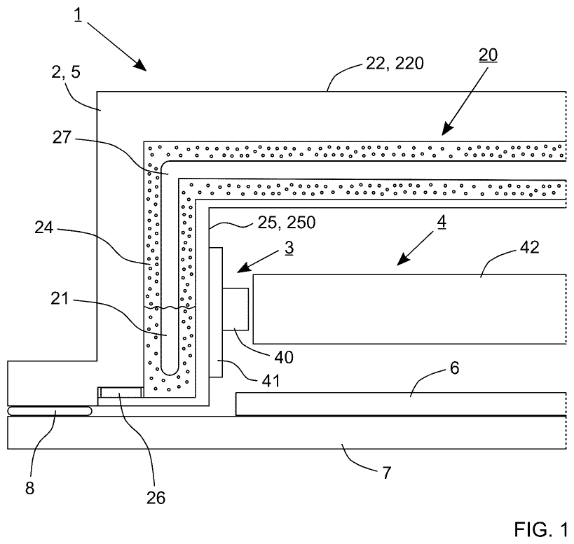

FIG. 1 schematically shows a first embodiment of an electronic device 1 according to the disclosure having an electronic component 3. In the example shown, the electronic device 1 is a display device, and the electronic component 3 is a light-emitting diode 40. The display device has a carrier element 2, which here serves as a housing 5 of the display device at the same time. The carrier element 2 is partly configured as a steam chamber 20. The steam chamber 20 has an inner wall 25 and an outer wall 22, which are connected, for example, by a soldered or welded connection 26. As an alternative, a crimped connection may also be implemented. The inner wall 25 is used as an evaporator 250 for a liquid 21 located in the steam chamber 20, and the outer wall 22 is used as a condenser 220. The steam chamber 20 is lined with a porous material 24, which encloses a cavity 27. A backlight 4 is used to backlight a display panel 6. The backlight 4 has a light guide 42, into which the light of the light-emitting diode 40 is laterally coupled. The light-emitting diode 40 is arranged, together with further light-emitting diodes 40, on a printed circuit board 41, which is arranged on the inner wall 25 of the steam chamber 20. The housing 5 is closed by a cover glass 7, which is connected to the housing by adhesive 8.

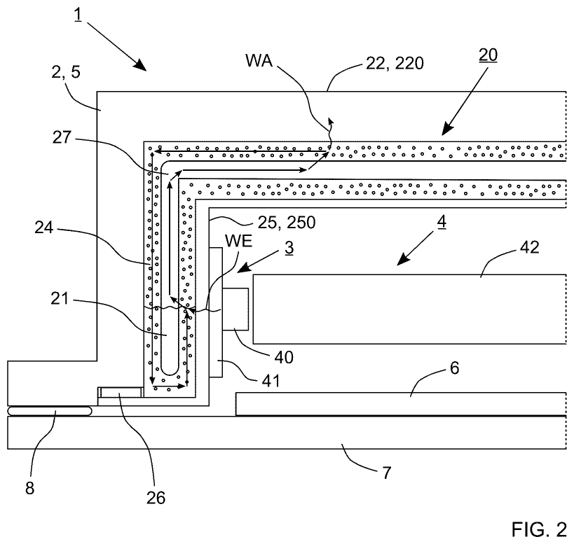

FIG. 2 illustrates the manner of operation of the steam chamber 20 of the electronic device 1 from FIG. 1. The heat input WE caused by the light-emitting diode 40 leads to evaporation of the liquid 21 located in the steam chamber 20 at the evaporator 250. During evaporation, the liquid 21 passes from the liquid phase to a gaseous phase. This requires thermal energy, which is stored in the resulting steam. The steam moves within the cavity 27 in the direction of the cooler regions of the steam chamber 20, that is to say to the condenser 220, where it condenses. During condensation, a phase transition from the gaseous phase to the liquid phase occurs, during which the heat stored in the steam is released and heat dissipation WA to the condenser 220 takes place. Owing to the pressure loss during condensation and the increase in pressure during evaporation, the steam always automatically flows to the cool regions of the steam chamber 20. Owing to the capillary effect in the porous material 24, possibly assisted by gravity, the liquid 21 is returned from the site of condensation to the site of evaporation. A continuous cycle is thus realized.

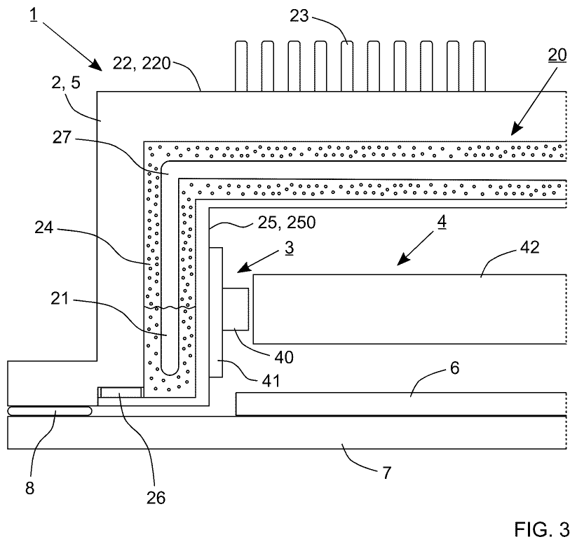

FIG. 3 schematically shows a second embodiment of an electronic device 1 according to the disclosure. The electronic device 1 is once again a display device. The display device is largely identical to the display device shown in FIG. 1. However, the outer wall 22 of the steam chamber 20 has cooling fins 23 in this case. The cooling fins 23 may increase the dissipation of heat to the surroundings.

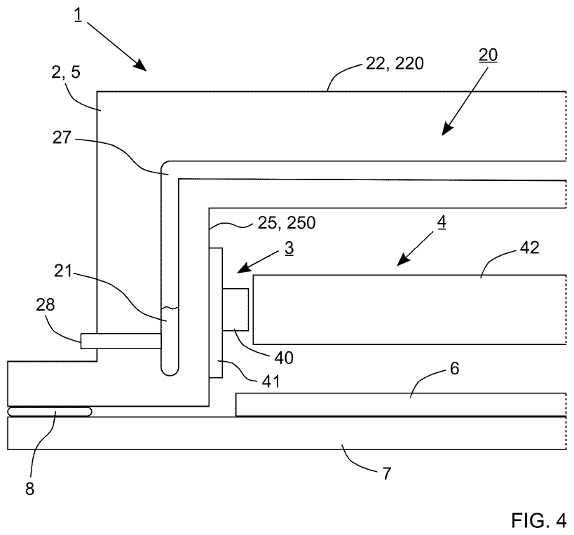

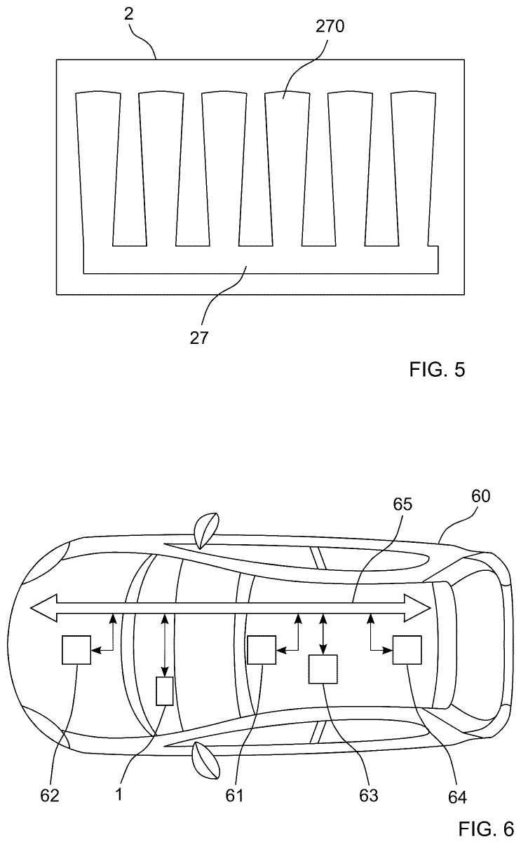

FIG. 4 schematically shows a third embodiment of an electronic device 1 according to the disclosure. The electronic device 1 is once again a display device. The display device is largely identical to the display device shown in FIG. 1. However, the carrier element 2 is manufactured by internal-pressure injection molding. For internal-pressure injection molding, casting material is first injected into a casting mold. The casting material is preferably a metal, for example a magnesium alloy, but suitable plastics may also be used. A temporary liquid or gaseous filler is then injected into the mold with the still liquid casting material in such a way that it acts as a core. The displacement of the casting material from the center firstly creates the required cavity 27 and secondly the casting material is pressed against the walls of the casting mold. Once the casting material has solidified, the filler escapes again. FIG. 5 schematically shows a possible design of the cavity 27. The cavity 27 comprises a number of channels 270, which are created by injecting the filler. The required liquid 21 may then be introduced into the cavity 27 and the hollow body may then be closed. A valve 28 is provided in the illustrated example for introducing the fluid 21. Since the steam chamber 20 is not lined with a porous material in this embodiment, the condensed liquid 21 has to be returned to the site of evaporation by gravity. Therefore, this embodiment is suitable for electronic devices 1 in which the electronic component 3, the heat of which has to be distributed, is arranged in such a way that the liquid 21 flows to the site of heat input due to gravity alone. One example of this is a vertically installed display device with an edge backlight arranged at the lower end.

FIG. 6 schematically shows a means of transportation 60 that uses an electronic device 1 according to the disclosure. The means of transportation 60 is a motor vehicle in this example. The motor vehicle has an electronic device 1 according to the disclosure, the electronic device being a display device arranged in a dashboard in this example. Data relating to the area surrounding the vehicle may be acquired by way of a sensor system 61. The sensor system 61 may comprise, in particular, environment recognition sensors, for example ultrasonic sensors, laser scanners, radar sensors, lidar sensors, or cameras. The information acquired by the sensor system 61 may be used to generate contents to be displayed for the display device. Further constituent parts of the motor vehicle in this example are a navigation system 62, which may be used to provide position information, and also a data transmission unit 63. By way of example, a connection to a backend, for example for receiving updated software for components of the motor vehicle, may be established by the data transmission unit 63. A memory 64 is present for storing data. Data is exchanged between the various components of the motor vehicle via a network 65.

1. An electronic device comprising:
a carrier element; and
at least one heat-producing electronic component, wherein the carrier element is configured as a steam chamber and is designed to distribute heat produced by the at least one heat-producing electronic component.

2. The electronic device as claimed in claim 1, wherein the at least one heat-producing electronic component is thermally connected to the carrier element.

3. The electronic device as claimed in claim 1, wherein the electronic device is a display device.

4. The electronic device as claimed in claim 3, wherein the at least one heat-producing electronic component is a light-emitting diode of a backlight.

5. The electronic device as claimed in claim 1, wherein the carrier element is configured as a housing.

6. The electronic device as claimed in claim 1, wherein an outer wall of the carrier element is configured as a heat sink.

7. The electronic device as claimed in claim 6, wherein the outer wall has cooling fins.

8. The electronic device as claimed in claim 1, wherein the carrier element is manufactured by internal-pressure injection molding.

9. The electronic device as claimed in claim 1, wherein the steam chamber is lined with a porous material.

10. A means of transportation comprising:
an electronic device comprising:
a carrier element; and
at least one heat-producing electronic component, wherein the carrier element is configured as a steam chamber and is designed to distribute heat produced by the at least one heat-producing electronic component.
